(19) United States
(12) Patent Application Publication
(10) Pub. No.: US 2012/0043986 A1
(43) Pub. Date: Feb. 23, 2012

(54) Junction box with test contact

(76) Inventors: Michael Richter, Schalksmuehle (DE); Dennis Gazke, Luedenscheid (DE)

(21) Appl. No.: 13/136,882

(22) Filed: Aug. 12, 2011

(30) Foreign Application Priority Data
Aug. 17, 2010 (DE) 102010034633.0-55

(51) Int. Cl. G01R 31/26

(52) U.S. Cl. 324/756.01

(57) ABSTRACT

A junction box for a solar module, including a base that is parallel to a mounting surface for the solar module; an inner cavity formed by a housing and closed by a cover; a connecting conductor for putting out electricity generated by the solar module and connected in the inner cavity with a contact for the solar module, and a test contact that is accessible in a direction substantially perpendicular to the base. The connecting conductor exits the inner cavity and is provided with a plug connector that is arranged in a support device at the junction box, wherein the test contact is electrically connected with a connecting contact of the plug connector of the connecting conductor, and wherein a function of the junction box is testable through feeding an electrical voltage into the test contact.

### RELATED APPLICATIONS

This patent application claims priority from and incorporates by reference German patent application 10 2010 034 633.0-55 filed on Aug. 17, 1010

### FIELD OF THE INVENTION

The invention relates to a junction box, in particular for a solar module, including a base that is parallel to an assembly surface at the module and an inner cavity formed by a housing and closed by a cover, wherein a solar module contact is connected within the housing with a connecting conductor for putting out electricity that is being generated, wherein the conductor exiting the inner cavity is provided with a plug connector which is arranged in a support device at the junction box.

### BACKGROUND OF THE INVENTION

Junction boxes of this type are known, for example, from DE 10 2007 023 210 B3 DE 10 2007 027 861 A1 and DE 10 2007 060 023 A1.

The need to support plug connectors of the connecting conductors through a support device at the housing substantially originates from the requirements of automatically producing solar modules. In order to produce solar modules in a fully automated manner the junction boxes to be mounted at the solar modules have to be deliverable in storage stacks in order to be machine feed able. Thus, the junction box is typically preassembled at the junction box manufacturer and provided with connecting conductors. In order to be able to deliver a neatly arranged stack the connecting conductors are directly secured at the junction box through plug-in connectors.

The defined arrangement of the plug connectors at the junction box is additionally used according to DE 10 2007 060 023 A1 to perform a functional check of the junction box. Thus, a test device contacts the contacts of the plug connectors and feeds electricity. Thus, various test procedures can be used to determine whether the connection between the plug connectors, connecting conductors and the functional components arranged within the junction boxes like, for example, bypass diodes are provided correctly.

However, it has become apparent that the position of the plug connectors and in particular of their connecting contacts as a function of their support devices at the junction box, the length of the connecting conductors and the weight load on the support devices resulting there from and as a function of additional influences has a certain tolerance. This necessitates complex control logics for the test robot which contacts the connection contacts of the plug connectors in order to perform a functional check of the junction box.

### BRIEF SUMMARY OF THE INVENTION

Thus, it is an object of the invention to provide a junction box for fully automated production which provides a defined position of the contacts to be used by a testing device and a simplification of the test procedure.

The object is achieved by a junction box with a base that is parallel to a mounting surface for the solar module, an inner cavity formed by a housing and closed by a cover, a connecting conductor for putting out electricity generated by the solar module and connected in the inner cavity with a contact for the solar module, and a test contact that is accessible in a direction substantially perpendicular to the base, wherein the connecting conductor exits the inner cavity and is provided with a plug connector that is arranged in a support device at the junction box, the test contact is electrically connected with a connecting contact of the plug connector of the connecting conductor, and in a function of the junction box is testable through feeding an electrical voltage into the test contact, in particular with the characterizing features according to which a test contact that is essentially accessible in a perpendicular direction relative to the basis is provided which is electrically connected with a connection contact of the plug connector of the connecting conductor and through which the function of the junction box is testable through feeding an electrical voltage.

Differently from the known prior art test procedure through contacting the connection contacts of the plug connectors arranged in the support device at the junction box by moving horizontally parallel to a base, the invention provides a test contact that is contacted in a perpendicular direction relative to the base, thus in a perpendicular direction relative to the mounting surface of the solar module. This has significant advantages with respect to the test routine. This way mounting the junction box and functionally testing it through contacting the connection conductors and the solar module conductors can be provided in one process step and in particular in one movement.

While it was required in the prior art to connect the junction box at the solar module through a movement oriented perpendicular to the mounting surface of the solar module and to establish the connection between solar module connector and the connecting conductor mechanically through welding or soldering, and parallel thereto, or in a separate process step to contact the connecting contact of the plug connectors for testing through the testing tools, thus in a movement oriented parallel to the mounting surface of the solar module, both processes can now be combined. The tool head which attaches the junction box according to the invention at the solar module initially includes assembly tools for connecting the connecting conductor and the solar module conductor. The tool head furthermore includes the necessary test pins which engage the vertically accessible test contacts. Thus, a functional test of the junction box can be performed through the test contacts in parallel with the assembly process.

Since the junction boxes typically include a higher number of contacts for solar module conductors in their interiors compared to the number of outgoing connecting conductors which in turn are connected with one another, in particular through bypass diodes, a very precise functional check can already be performed when assembling the junction box. When the test contacts and thus also the connecting conductors and also the contacts arranged within the junction box are engaged by a test device, respective circuits can simulate any option of electrical current flow when operating a solar module.

In an exemplary embodiment it is provided that the connection contact of the plug connector and the test contact form separate components in particular that the test contact is arranged at the junction box housing.

The separate configuration of the test contact and its separate arrangement at the junction box housing provides a defined position of the test contact which is independent from the dimensional and production tolerances of the support device and the plug connectors or from weight influences of the cables arranged at the plug connector.

Thus, it is furthermore provided that the test contact based on the arrangement of the plug connector at the support device is in electrical contact with the connecting contact of the plug connector. Thus, it is provided that the connection between the connecting contact of the plug connector and the test contact is established through inserting the plug connector into the support device and no separate manipulations are required.

An embodiment that is advantageous is one in which the junction box housing forms a plug-in mechanism that is complementary to the plug connector and serves as a support device, wherein the plug connector is arranged at the plug-in mechanism.

Contrary to the prior art support clamps and similar support devices, using the original plug connector mechanism for supporting the plug connector at the junction box has a substantial advantage in that a secure support with defined position is provided.

Thus, it is being considered that the complementary plug-in mechanism supports the test contact which is electrically connected with its connecting contact when the plug connector is arranged and the test contact is accessible through an opening that is oriented substantially perpendicular to the base.

The invention furthermore relates to junction boxes in which the connecting contact of the plug connector is essentially only accessible in horizontal direction due to its arrangement in the support device.

For a correct positional arrangement of the junction box with respect to the assembly and test tools it is provided that the junction box includes centering mechanisms through which it can be centered relative to a test tool.

An alternative embodiment of the junction box provides that the test contact is formed by the connecting contact of the plug connector which is accessible through an opening in the plug connector which is oriented substantially perpendicular to the base.

This provides in particular an alternative to a separate test contact which is arranged according to the invention at the junction box. However, it is necessary to assure before feeding electricity that the opening for test tapping is closed. This can be provided, for example, through the tool for mounting the junction box after testing.

### BRIEF DESCRIPTION OF THE DRAWINGS

The invention is described in more detail based on an exemplary embodiment with reference to drawings, wherein:

FIG. 1 illustrates a junction box according to the invention in a perspective view;

FIG. 2 illustrates the junction box according to FIG. 1 in a top view; and

FIG. 3 illustrates a sectional view of the junction box according to FIG. 2 along the section line III-III with the plug connector arranged at the junction box.

### DETAILED DESCRIPTION OF THE INVENTION

The drawings illustrate a junction box for solar modules that is designated overall with the reference numeral 10.

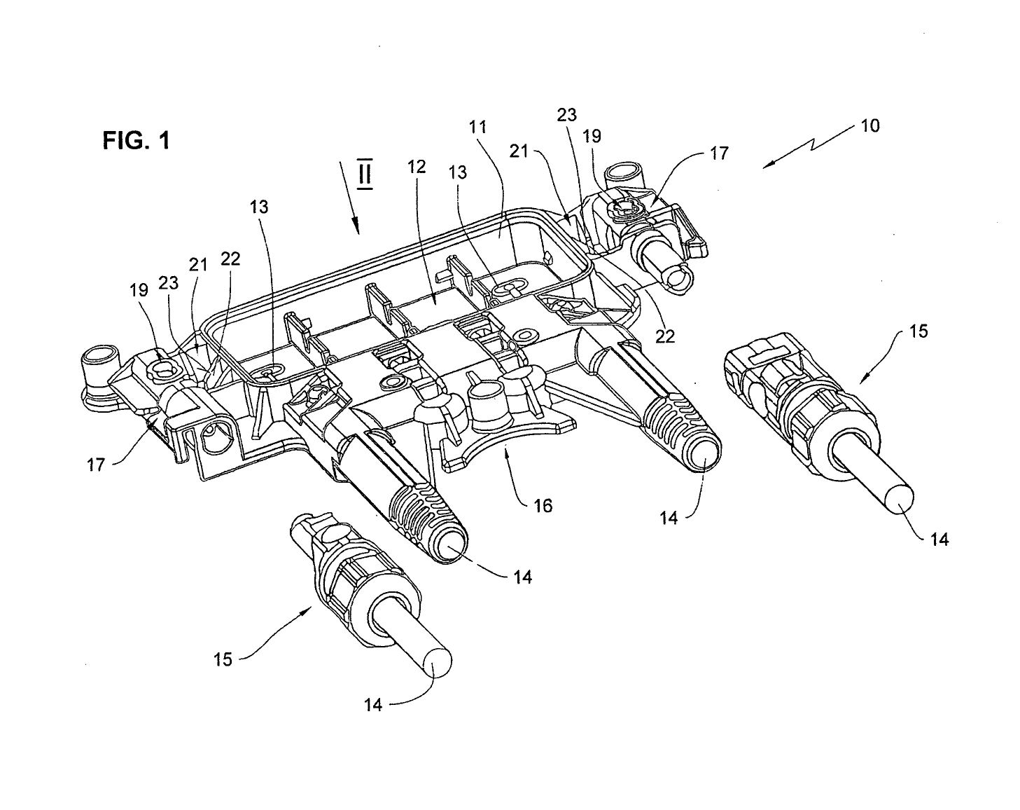

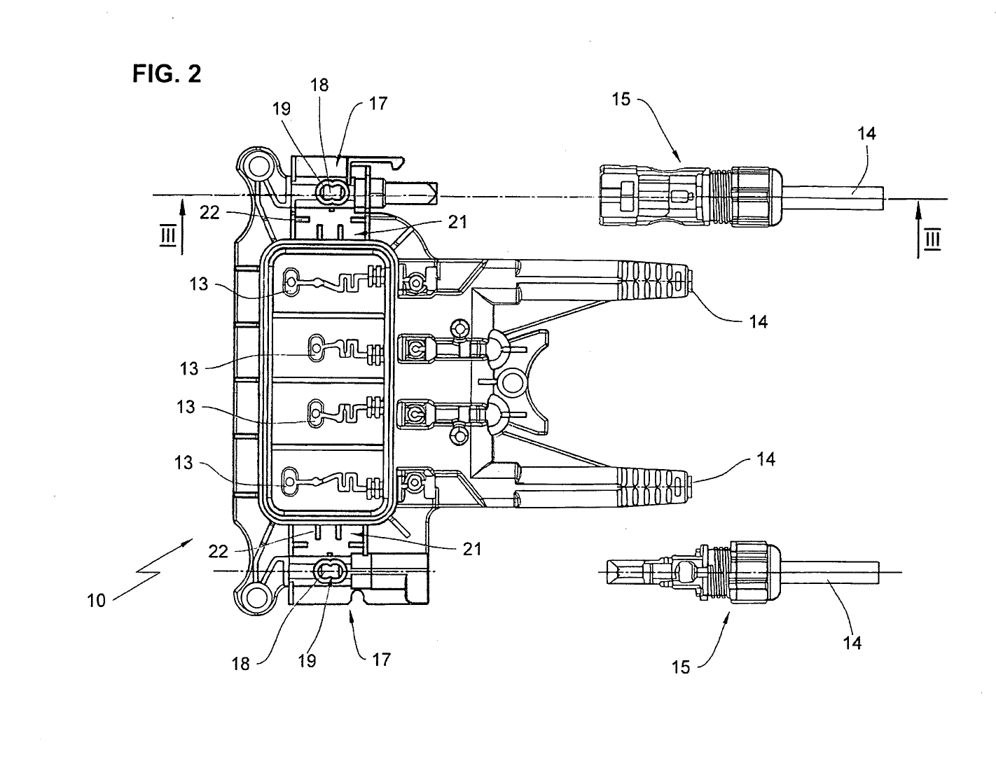

It is apparent from the perspective view in FIG. 1 and the top view in FIG. 2 of the junction box 10 according to the invention that the junction box includes a housing 11 which configures an inner cavity 12. Soldering or welding contacts 13 are arranged in the cavity 12, wherein the soldering or welding contacts 13 are electrically connected with the functional components embedded in the housing material, in particular with bypass diodes. The soldering or welding contacts 13 are attached at the solar module conductors (not illustrated) during assembly.

Connecting conductors 14 exiting the interior 12 of the housing are also electrically connected with the soldering or welding contacts 13, wherein the connecting conductors put out the electrical energy generated by the solar module. At their free ends the connecting conductors 14 are respectively provided with a plug connector 15. The visual separation of connecting conductors 14 illustrated in the drawings is only caused by the drawing technique. In fact the connecting conductors 14 form a non-interrupted strand which extends from the interior 12 of the housing to the plug connector 15.

The base 16 of the junction box 10 is formed by its bottom side. The junction box 10 is arranged with its bottom side at the solar module which is not illustrated.

The housing 11 of the junction box 10 forms respective support devices 17 for the plug connectors 15, wherein the support devices are arranged at the housing laterally adjacent to the inner cavity 12. It is of particular importance that each support device 17 forms a shape complementary plug-in mechanism with the associated plug connector 15. This means that the support device 17 forms the plug-in mechanism of a complementary plug for a plug connector 15 configured as a plug socket. The support device 17 includes a socket shaped plug-in mechanism for a plug connector 15 configured as a plug.

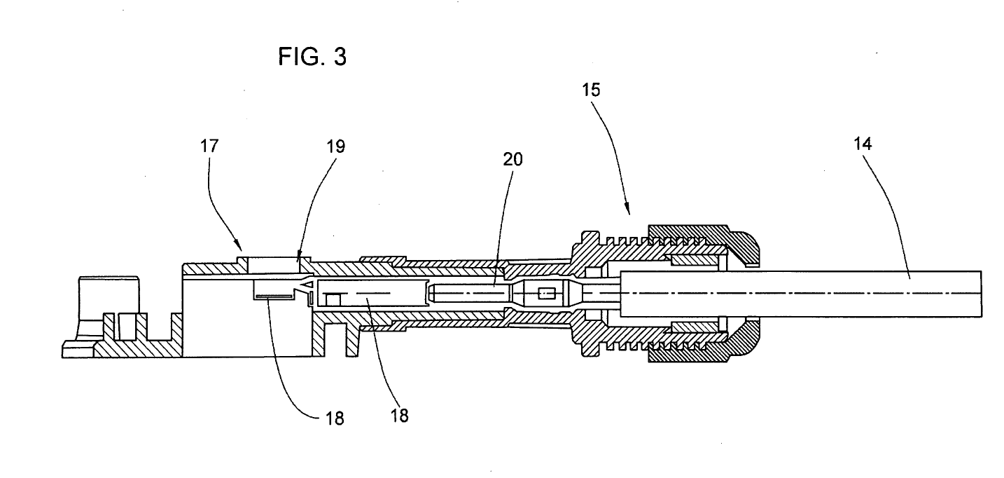

In addition to the plug-in mechanism complementary to the respective plug connector 15, the support devices 17 respectively include a test contact 18 (cf. FIG. 2) which is in turn configured plug-in complementary to the connecting contact 20 (c.f. FIG. 3) of the respective plug connector 15. A test tool can engage the test contacts 18 through vertically accessible openings 19 of the support devices 17.

FIG. 3 illustrates a sectional view according the sectional line III-III in FIG. 2, wherein the plug connector illustrated in FIG. 2 is inserted in FIG. 3 into its associated support device 17.

The illustration in FIG. 3 shows how the connecting contact 20 of the plug connector 15 contacts the plug complimentary test contact 18 when the plug connector 15 is inserted into the support device 17.

The junction box 10 according to the invention essentially has the following advantages.

Initially a junction box 10 is provided which forms a novel support device 17 for preassembled connecting conductors 14 and in particular their plug connectors 15. Through configuring the support device 17 according to the invention as a plug-in mechanism that is complementary to the associated plug connector 15 the plug connector 15 is safely and precisely positioned at the junction box. This is important in particular in order to provide preassembled junction boxes 10 in stacks or magazines for the fully automated production of solar modules, wherein the junction boxes can be retrieved by production robots in a simple manner.

In conjunction with the recited advantage assembly and functional checking of the junction box 10 according to the invention is simplified considerably. The support device 17 is not only plug-in compatible with respect to the plug connector 15. It is furthermore provided with a test contact which contacts the connecting contact 20 of the plug connector 15 when the plug connector 15 is applied to the support device 17.

An opening 19 of the support device 17, wherein the opening is oriented perpendicular with respect to the base 16 facilitates an access to the test contact 18 through a respective test tool. The base 16 is oriented parallel to the mounting surface of the solar module.

When mounting the junction box 10 on a solar module that is not illustrated the junction box is applied to the solar module in a perpendicular direction to the base 16 or in a perpendicular direction to the mounting surface of the solar module and attached. The tools engage the soldering or welding contacts 13 also in the perpendicular direction in order to connect them with solar module connecting conductors. Alternatively the contacts not illustrated herein are mechanically connected with solar module conductors through clamping in the same tool movement direction.

The junction box 10 according to the invention with its vertically accessible openings 19 and vertically accessible test contacts 18 now facilitates for the first time a purely vertical movement of the test tool for functional testing of the junction box 10 which is not possible in the prior art. The horizontal engagement of the connecting contacts of the plug connectors 15, wherein the connecting contacts are not completely defined with respect to their positions, which was required in the prior art, thus can be omitted. This also yields another substantial advantage. The test contacts are configured in a clearly defined position as components of the junction box 10. Contrary to the plug connectors 15 supported with a certain clearance tolerance in the support devices 17 according to the prior art the junction box according to the invention does not provide any position tolerance for the test contacts 18.

Consequently the assembly tool for the junction boxes 10 can integrate all tools for assembling the junction boxes 10, the solder/weld contacts 13 and for functional testing in an assembly line for solar modules so that assembly and functional testing can be combined into one process step.

In case it is required for assembly, centering bosses at the tools can engage the centering openings 21 at the junction boxes. Centering bars 22 with slanted surfaces 23 oriented towards the centering boss support the centering function.

The centering aids 21-23 can be used on the one hand side for centering the junction box 10 relative to the assembly tool when it is received in the assembly tool. The centering aids, however, can be used during an assembly process performed in plural steps and by plural tools for readjusting the junction boxes 10 on the solar panels when switching from one assembly tool to another. Thus, care only has to be taken that the attachment device between the junction box 10 and the solar module, typically a gluing device cures respectively slowly and facilitates re-centering the junction box 10 during the particular assembly steps.

### REFERENCE NUMERALS AND DESIGNATIONS

10 junction box
11 housing of 10
12 inner cavity
13 solar module soldering/welding contact
14 connecting conductor
15 plug connector
16 base
17 support device
18 test contact
19 opening
20 connecting contact of 15
21 centering opening
22 centering bar
23 slanted surfaces

What is claimed is:

1. A junction box for a solar module, comprising:
a base that is parallel to a mounting surface for the solar module;
an inner cavity formed by a housing and closed by a cover;
a connecting conductor for putting out electricity generated by the solar module and connected in the inner cavity with a contact for the solar module; and
a test contact that is accessible in a direction substantially perpendicular to the base,
wherein the connecting conductor exits the inner cavity and is provided with a plug connector that is arranged in a support device at the junction box,
wherein the test contact is electrically connected with a connecting contact of the plug connector of the connecting conductor, and
wherein a function of the junction box is testable through feeding an electrical voltage into the test contact.

2. The junction box according to claim 1, wherein the connecting contact of the plug connector and the test contact are separate components.

3. The junction box according to claim 1, wherein the test contact is arranged at the housing.

4. The junction box according to claim 2, wherein the test contact is in electrical contact with the connecting contact of the plug connector.

5. The junction box according to claim 1,
wherein the housing forms a plug-in mechanism that is complementary to the plug connector and configured as a support device, and
wherein the plug connector is arranged at the plug-in mechanism.

6. The junction box according to claim 5,
wherein the plug-in mechanism supports the test contact which is electrically connected with its connecting contact when the plug connector is arranged at the plug-in mechanism, and
wherein the test contact is accessible through an opening oriented substantially perpendicular to the base.

7. The junction box according to claim 1, wherein the connecting contact of the plug connector is accessible only in a substantially horizontal direction since the plug connector is arranged in the support device.

8. The junction box according to claim 1, wherein the junction box includes centering mechanisms configured to center the junction box relative to a test tool.

9. The junction box according to claim 1,
wherein the test contact is formed by the connecting contact of the plug connector, and
wherein the connecting contact is accessible through an opening in the plug connector where the opening is substantially oriented perpendicular to the base.

10. The junction box according to claim 2, wherein the test contact is arranged at the housing.

11. The junction box according to claim 2,
wherein the housing forms a plug-in mechanism that is complementary to the plug connector and configured as a support device, and
wherein the plug connector is arranged at the plug-in mechanism.

12. The junction box according to claim 3,
wherein the housing forms a plug-in mechanism that is complementary to the plug connector and configured as a support device, and
wherein the plug connector is arranged at the plug-in mechanism.

13. The junction box according to claim 4,
wherein the housing forms a plug-in mechanism that is complementary to the plug connector and configured as a support device, and
wherein the plug connector is arranged at the plug-in mechanism.
